(19) United States
(12) Patent Application Publication
(10) Pub. No.: US 2010/0231412 A1
(43) Pub. Date: Sep. 16, 2010

(54) DEVICE, IN PARTICULAR A POWER QUALITY METER AND A POWER QUALITY DEVICE

(76) Inventors: Dirk Jürgens, Nurnberg (DE); Daniel Saksida, Stein (DE)

Correspondence Address: HARNESS, DICKEY & PIERCE, P.L.C., P.O.BOX 8910, RESTON, VA, 20195, US

(21) Appl. No.: 12/719,891

(22) Filed: Mar. 9, 2010

(30) Foreign Application Priority Data
Mar. 11, 2009 (DE) 10 2009 012 648.1

(51) Int. Cl. G08C 19/16; G01R 21/00; G06F 19/00

(52) U.S. Cl. 340/870.01; 702/62

(57) ABSTRACT

A device is disclosed, in particular a power quality meter and power quality device, for determining and recording data relating to an electrical power supply system on the basis of analog electrical signals, in particular voltage, current and frequency, which are output and/or derived from the electrical power supply system and are passed to the inputs of the device. In at least one embodiment, the device includes a measurement channel, which is connected downstream from the inputs, for measuring the electrical signals, and a software-controlled processor, which is connected downstream from the measurement channel, for determining the data. In order to determine the quality of power supply systems with little effort, in at least one embodiment a communication channel is provided which has a communication interface which is likewise connected to the inputs and via which the device can communicate by cable via the electrical lines of the power supply system with correspondingly equipped other devices.

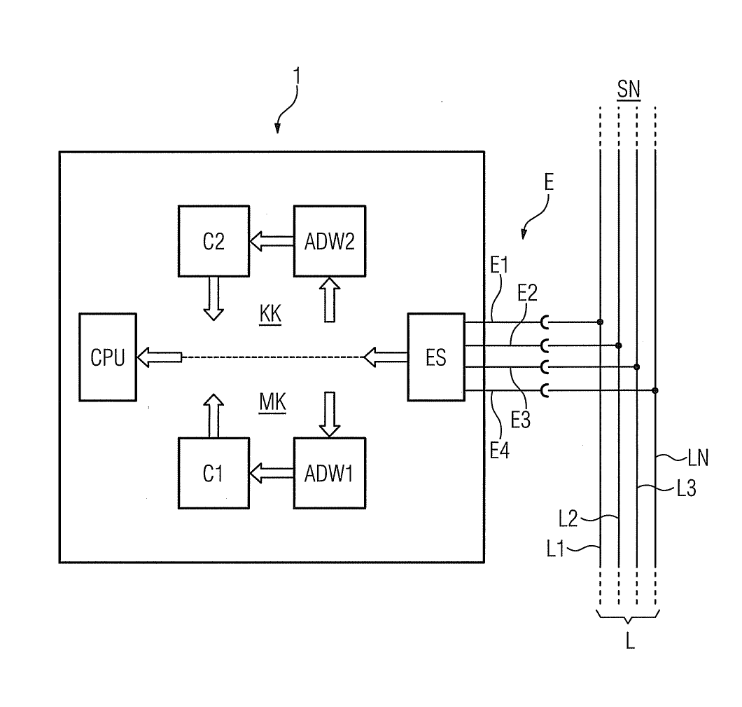

### PRIORITY STATEMENT

The present application hereby claims priority under 35 U.S.C. §119 on German patent application number DE 10 2009 012 648.1 filed Mar. 11, 2009, the entire contents of which are hereby incorporated herein by reference.

### FIELD

At least one embodiment of the invention generally relates to a device for determining and recording data relating to an electrical power supply system.

### BACKGROUND

Power quality meters (PQM) and power quality devices (PQD) are known as devices which determine and record data relating to an electrical power supply system, in order to determine its quality. For this purpose, the appropriate electrical signals from the power supply system are applied to the inputs of the device, that is to say essentially the voltage and the current (generally converted to appropriate voltage) and their frequency. The signals which are applied to the inputs are measured, digitized and processed by a software-controlled processor.

It is also known for communication to take place via the electrical lines of the power supply system (powerline communication).

### SUMMARY

In at least one embodiment of the invention provides a device which makes it possible to determine the quality of power supply systems, with little effort.

In at least one embodiment, a solution provides that a communication channel is provided which has a communication interface which is likewise connected to the inputs and via which the device can communicate by cable via the electrical lines of the power supply system with correspondingly equipped other devices. This additionally makes it possible to draw (indirect) conclusions about the quality of the supply lines and therefore of the power supply system, without any need for an additional powerline meter. In addition, the communication channel provides the capability to carry out remote maintenance and diagnosis of the device. Furthermore, the device can be used to obtain additional information about the noise level and attenuation of the powerline signal. In addition to communication, this also allows analysis and content assessment thereof.

The complexity is further reduced if the measurement channel and the communication interface of the communication channel are connected to the voltage inputs.

The device can be simplified if the inputs are directly followed by a common input stage.

Further technical simplification is achieved if the measurement channel and the communication channel are connected for data transmission purposes to the common software-controlled processor.

In order to facilitate the various objects relating to analysis and assessment of the measurement channel and communication channel, it is proposed that the measurement channel and the communication channel each have their own controller.

In order to improve the quality assessment, it is proposed that the communication signals are analyzed and/or the protocol of the communication signals is assessed.

### BRIEF DESCRIPTION OF THE DRAWINGS

An embodiment of the invention will be described in the following text by way of example using a drawing, whose single FIGURE shows a device 1 which is connected by inputs E (E1, E2, E3, E4) to the lines L (L1, L2, L3, LN (neutral conductor)) of a power supply system SN.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the FIGURE.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGURE. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the FIGURE. It will be understood that the spatially relative terms are intended to encompass different orientations of the device in use or operation in addition to the orientation depicted in the FIGURE. For example, if the device in the FIGURE is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

The AC voltages of the three phases of the power supply system SN with respect to the neutral conductor LN are in this case applied as analog electrical signals to the inputs E (E1, E2, E3), with the frequency of the power supply system SN as the fundamental frequency. It is, of course, also possible to detect the alternating currents flowing through the lines L as a further analog electrical signal, in which case the alternating currents are for this purpose expediently converted in advance to proportional electrical voltages.

The inputs E are connected to a common input stage ES, which in this case forms the physical interface to the power supply system SN.

The output side of the input stage ES is connected to two channels, a measurement channel MK and a communication channel KK. As a special feature, this already includes the communication interface of the communication channel KK which, of course, can also be connected to the input of the communication channel KK.

In the measurement channel MK, the AC voltages of the three phases are digitized by means of an A/D converter ADW1, before they are supplied to a controller C1, which carries out appropriate preprocessing. The preprocessed signals are then transmitted from the controller C1 to a software-controlled processor CPU which uses them to determine the data (relating to the quality (power quality)) of the power supply system SN, and to appropriately store (record) it (in data storage media).

Communication data is also transmitted via the power supply system SN, that is to say via the lines L, with the aid of predetermined protocols (powerline communication). The communication data is then likewise available as communication signals (powerline signals) at the output of the input stage ES, and is processed separately from the measurement signals in the communication channel KK.

In the communication channel KK, it is first of all digitized by an A/D converter ADW2, and is then passed on to a controller C2 which appropriately conditions the powerline signals and then transmits them to the (common) processor CPU for further processing.

The processor CPU likewise derives the quality (the power quality) of the power supply system SN from this. The quality of the power supply system SN is therefore determined on the basis of the electrical signals both of the measurement channel MK and of the communication channel KK in that, in this case, at least the signal strength and the quality, that is to say the noise level as well as the attenuation, of the powerline signals are used.

Furthermore, the processor CPU can also itself assess the quality of the powerline communication, by analysis and content assessment of the protocol of the powerline communication.

If the information transmitted by way of powerline communication is intended for the device 1, this information is evaluated by the processor CPU in the device 1, for remote maintenance and diagnosis purposes, and, if required, appropriate information is sent back to the information transmitter. The device 1 can therefore also communicate by cable via the communication channel KK with appropriately equipped devices, when these devices are connected to the power supply system SN.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combineable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A device for determining and recording data relating to an electrical power supply system on the basis of analog electrical signals which are at least one of output and derived from the electrical power supply system and are passed to the inputs of the device, the device comprising:
a measurement channel, connected downstream from the inputs, to measure the electrical signals;
a software-controlled processor, connected downstream from the measurement channel, to determine the data; and
a communication channel, including a communication interface connected to the inputs and via which the device can communicate by cable via the electrical lines of the power supply system with correspondingly equipped other devices.

2. The device as claimed in claim 1, wherein the measurement channel and the communication interface of the communication channel are connected to the inputs.

3. The device as claimed in claim 1, wherein the inputs are directly followed by a common input stage.

4. The device as claimed in claim 1, wherein the measurement channel and the communication channel are connected for data transmission purposes to the software-controlled processor.

5. The device as claimed in claim 1, wherein the measurement channel and the communication channel each include their own controller.

6. The device as claimed in claim 1, wherein at least one of the communication signals are analyzed and the protocol of the communication signals is assessed.

7. The device as claimed in claim 6, wherein data relating to the electrical power supply system is determined on the basis of the at least one of the analysis of the communication signals and the assessment of the protocol of the communication signals.

8. The device as claimed in claim 1, wherein the device is at least one of a power quality meter and power quality device.

9. The device as claimed in claim 1, wherein the analog electrical signals include at least one of voltage, current and frequency.

10. The device as claimed in claim 2, wherein the inputs are directly followed by a common input stage.

11. The device as claimed in claim 2, wherein the measurement channel and the communication channel are connected for data transmission purposes to the software-controlled processor.

12. The device as claimed in claim 2, wherein the measurement channel and the communication channel each include their own controller.
